(19) United States
(12) Patent Application Publication
(10) Pub. No.: US 2026/0032877 A1
(43) Pub. Date: Jan. 29, 2026

(54) HIGH-FREQUENCY CIRCUIT

(71) Applicant: ANRITSU CORPORATION, Kanagawa (JP)

(72) Inventors: Yasuki HIRAKAWA, Kanagawa (JP); Takato TOKUYAMA, Kanagawa (JP); Shunichi KANEOKA, Kanagawa (JP); Kohei MIYAKE, Kanagawa (JP)

(21) Appl. No.: 19/232,935

(22) Filed: Jun. 10, 2025

(30) Foreign Application Priority Data
Jul. 26, 2024 (JP) 2024-121028

(51) Int. Cl. H05K 9/00

(52) U.S. Cl. CPC H05K 9/0016; H05K 9/0032; H05K 9/0037

(57) ABSTRACT

A high-frequency circuit includes a printed circuit board on which a circuit including a plurality of electronic components is disposed, a shield case that is electrically connected to a ground of the printed circuit board and covers the circuit, and at least one spring contact that is electrically connected to the ground in a space formed by the printed circuit board and an inner wall of the shield case, in which the shield case includes a frame that is surface-mounted on the ground and is electrically connected to the ground, and a cover that includes a ceiling surface facing the printed circuit board and is electrically connected to the frame by being in contact with the frame, and the spring contact electrically connects the ground and the cover by being in contact with a part of the ceiling surface.

### TECHNICAL FIELD

The present invention relates to a high-frequency circuit and, more particularly, to a high-frequency circuit provided with a shield case.

### BACKGROUND ART

A radio frequency (RF) circuit is used with a shield case covering each circuit block in order to ensure isolation between the circuit blocks. A cavity resonance frequency of a space partitioned by the shield case is determined by a size and a shape of the space. At the cavity resonance frequency, the isolation of the space is 0 dB, which poses a problem in RF circuit design.

When the size of the space partitioned by the shield case is large, there is a disadvantage of a lower cavity resonance frequency, but there is an advantage of making it easier to arrange electronic components, thereby simplifying the design of a printed circuit board. Therefore, it is desired to suppress the cavity resonance and increase the size of the space of the shield case. Here, suppressing the cavity resonance means increasing the cavity resonance frequency to be higher than an operating frequency of the circuit block.

Conventionally, a method of attaching a radio wave absorber through trial and error has been employed as a method of suppressing cavity resonance.

Additionally, a technique is also known in which a radio wave absorber that includes grooves for individually covering a plurality of circuits configured on a circuit board ensures isolation between the plurality of circuits (for example, see Patent Document 1).

### RELATED ART DOCUMENT

### [Patent Document]

[Patent Document 1] JP-A-2010-199417

### DISCLOSURE OF THE INVENTION

### Problem that the Invention is to Solve

However, since there is no method of predicting in advance how the cavity resonance can be suppressed by the radio wave absorber, even in the technique disclosed in Patent Document 1, there has been a problem that the shape of the groove had to be determined through trial and error.

The present invention has been made in order to solve such a conventional problem, and an object of the present invention is to provide a high-frequency circuit capable of easily predicting and controlling a cavity resonance frequency in a shield case.

### Means for Solving the Problem

In order to solve the above-described problem, according to the present invention, there is provided a high-frequency circuit including: a printed circuit board (10) on which a circuit (21 to 27)) including a plurality of electronic components (11) is disposed; a shield case (31, 32, 36, 37) that is electrically connected to a ground (12, 13) of the printed circuit board and covers the circuit; and at least one connection conductor (15) that is electrically connected to the ground in a space formed by the printed circuit board and an inner wall of the shield case, in which the shield case includes a side wall portion (41 to 47) that is surface-mounted on the ground and is electrically connected to the ground, and a lid portion (51) that includes a ceiling surface (52) facing the printed circuit board and is electrically connected to the side wall portion by being in contact with the side wall portion, and the connection conductor electrically connects the ground and the lid portion by being in contact with a part of the ceiling surface.

With this configuration, the high-frequency circuit according to the present invention can achieve an effect as if the space formed by the printed circuit board and the inner wall of the shield case is made narrower, thereby increasing the cavity resonance frequency without using a radio wave absorber.

In addition, since the disposition of the connection conductor, which increases the cavity resonance frequency to be higher than the operating frequency, can be predicted through electromagnetic field simulation, the high-frequency circuit according to the present invention can reduce man-hours required for performance verification.

Additionally, the high-frequency circuit according to the present invention can facilitate the disposition of the electronic components on the printed circuit board because the cavity resonance frequency can be increased using the disposition of the connection conductor even in a case where the size of the space partitioned by the shield case is increased, thereby reducing design man-hours.

Further, the high-frequency circuit according to the present invention can effectively suppress cavity resonance by disposing the connection conductor in the vicinity of a center of the space of the shield case, thereby not affecting a degree of freedom in disposition of a plurality of other electronic components.

Furthermore, in the high-frequency circuit according to the present invention, the connection conductor may be a spring contact (15) including a contact portion (17) that elastically comes into contact with the ceiling surface.

With this configuration, the high-frequency circuit according to the present invention allows the ground of the printed circuit board and the lid portion of the shield case to be electrically connected reliably and easily, by covering the side wall portion with the lid portion of the shield case after disposing the plurality of electronic components and the side wall portion of the shield case on the printed circuit board.

In order to solve the above-described problem, according to the present invention, there is provided a cavity resonance suppression method in a high-frequency circuit (100) including a printed circuit board (10) on which a circuit (21 to 27) including a plurality of electronic components (11) is disposed, and a shield case (31, 32, 36, 37) that is electrically connected to a ground (12, 13) of the printed circuit board and covers the circuit, the shield case including a side wall portion (41 to 47) that is surface-mounted on the ground and is electrically connected to the ground, and a lid portion (51) that includes a ceiling surface (52) facing the printed circuit board and is electrically connected to the side wall portion by being in contact with the side wall portion, the method including: electrically connecting the ground and the lid portion by bringing at least one connection conductor (15), which is electrically connected to the ground, into contact with a part of the ceiling surface in a space formed by the printed circuit board and an inner wall of the shield case.

Further, in the cavity resonance suppression method according to the present invention, a spring contact (15) including a contact portion (17) that elastically comes into contact with the ceiling surface may be used as the connection conductor.

### Advantage of the Invention

The present: invention provides a high-frequency circuit capable of easily predicting and controlling a cavity resonance frequency in a shield case.

### BRIEF DESCRIPTION OF THE DRAWINGS

FIG. 1 is a plan view showing a configuration of a high-frequency circuit according to an embodiment of the present invention.

FIG. 2 is a perspective view showing the configuration of the high-frequency circuit according to the embodiment of the present invention.

FIG. 3 is a side view showing a main part of the configuration of the high-frequency circuit according to the embodiment of the present invention.

FIG. 4 shows a substrate surface of a printed circuit board in the high-frequency circuit according to the embodiment of the present invention.

FIGS. 5A to 5C are perspective views showing simulation models of the high-frequency circuit according to the embodiment of the present invention, in which FIG. 5A shows a model with one spring contact disposed in the vicinity of a center of the shield case, FIG. 5B shows a model with two spring contacts disposed 25 mm apart from each other in the shield case, and FIG. 5C shows a model with two spring contacts disposed 5 mm apart from each other in the vicinity of the center of the shield case.

FIG. 6 is a side view and a plan view of FIG. 5A.

FIG. 7 is a graph showing transmission characteristics of the models shown in FIGS. 5A to 5C and transmission characteristics of a model in which no spring contact is disposed.

FIG. 8 is a graph showing transmission characteristics of the simulation model and transmission characteristics of an experimental board.

FIG. 9 is a diagram showing electric field distributions of the models shown in FIGS. 5A to 5C and an electric field distribution of the model in which no spring contact is disposed.

### BEST MODE FOR CARRYING OUT THE INVENTION

First, an embodiment of a high-frequency circuit according to an embodiment of the present invention will be described with reference to the drawings. It should be noted that the dimensional ratio of each component in each drawing does not necessarily match the actual dimensional ratio.

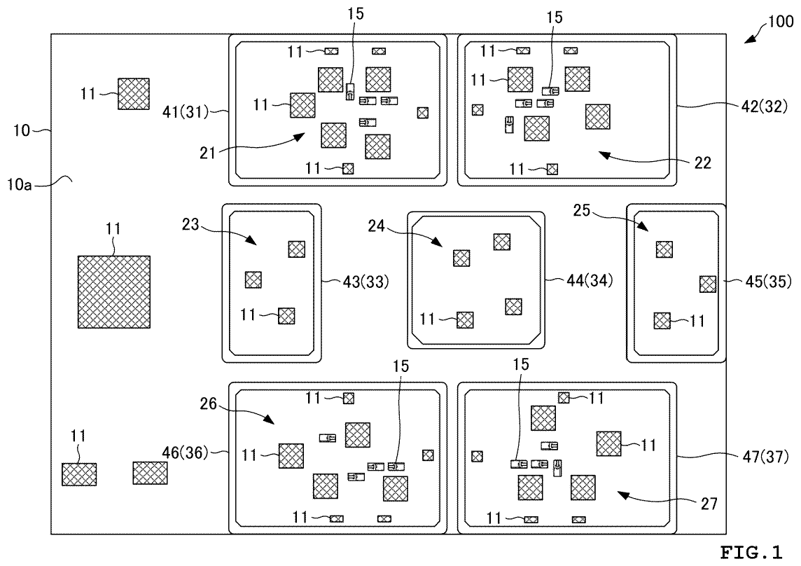

As shown in FIG. 1, a high-frequency circuit 100 includes circuits 21 to 27 that include a plurality of electronic components 11, a printed circuit board 10 on which the circuits 21 to 27 are disposed, shield cases 31 to 37 that cover the circuits 21 to 27, respectively, and spring contacts 15 as connection conductors.

The shield cases 31 to 37 include frames 41 to 47 as side wall portions and covers as lid portions respectively attached to the frames 41 to 47, but only the frames 41 to 47 of the shield cases 31 to 37 are shown in FIG. 1.

In the example of FIG. 1, seven circuits 21 to 27 are formed on one substrate surface 10a of the printed circuit board 10. Similarly, a plurality of circuits may be formed on the other substrate surface of the printed circuit board 10.

The shield cases 31 to 37 are metal housings that cover the circuits 21 to 27 disposed on the printed circuit board 10 and that prevent noise from being input from the outside or from other circuits, and for example, BMI-S-203, BMI-S-209, BMI-S-210, and the like manufactured by Laird Technologies, Inc. can be suitably used.

The original frames 41 to 47 include portions that are picked up by a suction nozzle of a mounting machine, but FIG. 1 shows a state in which the picked-up portions have been cut after the frames 41 to 47 have been mounted on the printed circuit board 10. The frames 41 to 47 are mounted to stand perpendicular to the substrate surface 10a of the printed circuit board 10.

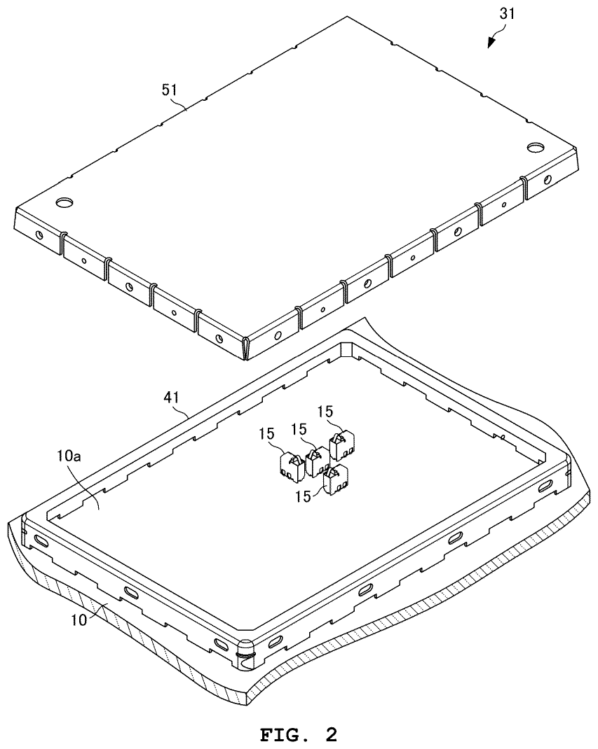

FIG. 2 shows a state before the cover 51 of the shield case 31 is attached to the frame 41. In FIG. 2, the plurality of electronic components 11 are not shown. Hereinafter, the shield case 31 will be described as a representative example, but the basic configuration of the other shield cases 32 to 37 is the same as that of the shield case 31.

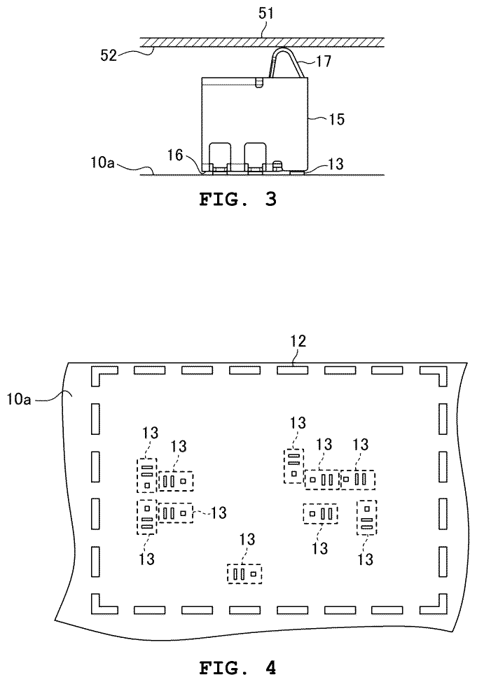

As shown in FIG. 3, the cover 51 includes a ceiling surface 52 that is parallel to and faces the substrate surface 10a of the printed circuit board 10 in a state of being attached to the frame 41. In addition, the cover 51 is attached to the frame 41 so that a peripheral edge portion of the cover 51 is electrically connected to the frame 41 by being in contact with the frame 41.

It is desirable that the sizes of the shield cases 31 to 37 correspond to the sizes and the maximum operating frequencies of the circuits 21 to 27, respectively.

For example, BMI-S-210 is used as the shield cases 31, 32, 36, and 37 in the circuits 21, 22, 26, and 27. The size of the frame of BMI-S-210, that is, the frames 41, 42, 46, and 47, is as follows: a long side is 44.00±0.10 mm, a short side is 30.50±0.10 mm, and a height is 3.00±0.10 mm.

FIG. 4 shows a part of grounds 12 and 13 provided on the substrate surface 10a of the printed circuit board 10. The grounds 12 and 13 are electrically connected to a common high-frequency ground (RF ground) (not shown) of the printed circuit board 10.

The frame 41 of the shield case 31 is surface-mounted on the ground 12 by reflow soldering, thereby electrically connecting the ground 12 and the frame 41.

The spring contact 15, which will be described below, is surface-mounted on the ground 13 by reflow soldering.

The operating frequency of the circuit 21 is, for example, 6 GHZ. In a case where BMI-S-210 is mounted on the printed circuit board 10 as the shield case 31 without using the spring contact 15, the cavity resonance frequency of the shield case 31 is approximately 5.9 GHZ, which affects the operating frequency of 6 GHZ.

The high-frequency circuit 100 of the present embodiment includes at least one spring contact 15 that electrically connects the ground 13 of the printed circuit board 10 and the cover 51 of the shield case 31 in a space with a substantially rectangular parallelepiped shape, which is formed by the printed circuit board 10 and an inner wall of the shield case 31, in order to increase the cavity resonance frequency of the space in the shield case 31 to be higher than the operating frequency.

For example, as the spring contact 15, SMAR-CFO275013A capable of automatic reflow mounting, which is manufactured by T. P. S. CREATIONS CO., LTD., can be suitably used. As shown in FIG. 3, a bottom portion 16 of SMAR-CFO275013A is electrically connected to the ground 13 of the printed circuit board 10.

The spring contact 15 includes a spring-like contact portion 17, and a movable range in a height direction is 2.7 to 3.5 mm. In a state in which the cover 51 is attached to the frame 41, the height of the ceiling surface 52 of the cover 51 of the shield case 31 is 3 mm from the substrate surface 10a of the printed circuit board 10. Therefore, in a state in which the cover 51 is attached to the frame 41, the contact portion 17 of the spring contact 15 elastically comes into contact with a part of the ceiling surface 52 of the cover 51 of the shield case 31 to electrically connect the ground 13 and the cover 51.

Hereinafter, a result of evaluating the cavity resonance frequency in the shield case 31 in the high-frequency circuit 100 of the present embodiment through electromagnetic field simulation will be described.

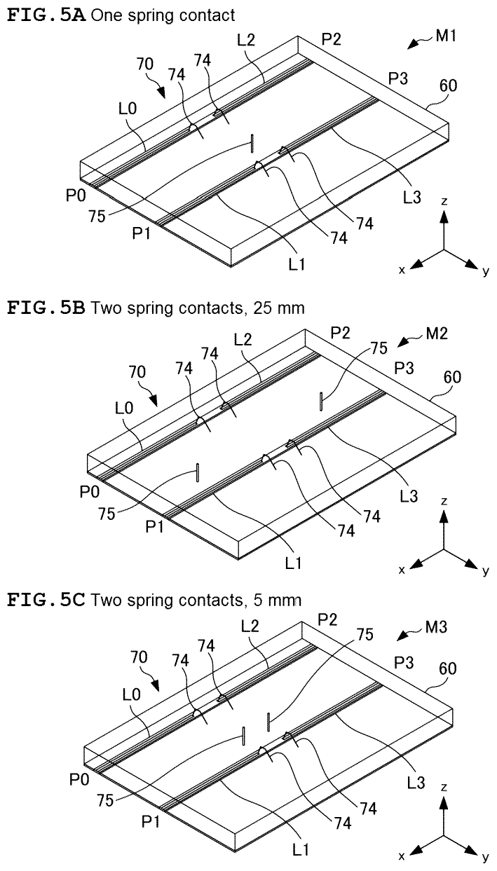

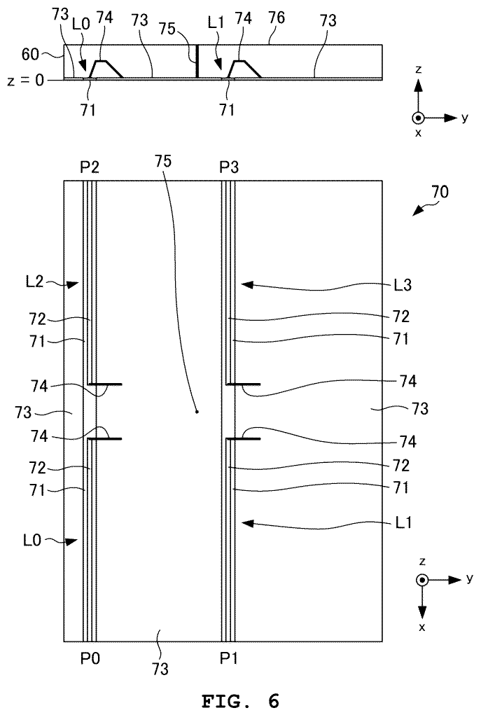

FIGS. 5A to 5C and 6 are views showing simulation models. FIG. 6 is a side view and a plan view of FIG. 5A.

The models shown in FIGS. 5A to 5C simulate a situation in which the printed circuit board 10 on which the spring contact 15 is disposed is covered with BMI-S-210 (hereinafter, also referred to as a “shield case 60”). In this model, the spring contact 15 is simulated by a cylindrical conductor.

Four microstrip lines L0, L1, L2, and L3 are formed on a printed circuit board 70 of the model. Ends of the microstrip lines L0, L1, L2, and L3 are defined as an input port P0 and three output ports P1, P2, and P3.

Each of the microstrip lines L0 to L3 includes a dielectric 71, a strip conductor 72 disposed on an upper surface of the dielectric 71, and a ground (not shown) disposed at z<0. Additionally, a ground 73 is disposed in a region where the microstrip lines L0 to L3 are not formed at z>0.

The microstrip lines L0 and L2 are configured such that central portions of the strip conductors are cut with respect to the microstrip lines with a length in a longitudinal direction of the printed circuit board 70. The same applies to the microstrip lines L1 and L3.

The cut end portion of each strip conductor 72 of the microstrip lines L0 to L3 is connected to the ground 73 by a conductive wire 74, thereby forming four short antennas.

That is, the simulation model is a model configured to intentionally facilitate cavity resonance by increasing the radiation and spatial coupling of the microstrip lines L0 to L3, which are four short antennas.

FIG. 5A shows a model (hereinafter, also referred to as a “model M1”) with one cylindrical spring contact 75 disposed in the vicinity of the center of the shield case 60. FIG. 5B shows a model (hereinafter, also referred to as a “model M2”) with two cylindrical spring contacts 75 disposed 25 mm apart from each other in an x direction in the shield case 60. FIG. 5C shows a model (hereinafter, also referred to as a “model M3”) with two cylindrical spring contacts 75 disposed 5 mm apart from each other in the x direction in the vicinity of the center of the shield case 60.

Main parameters of the simulation are as follows.
Thickness of dielectric 71: 0.2 mm
Thickness of strip conductor 72: 0.04 mm
Thickness of upper ground 73: 0.24 mm
Shield case 60: 44 mm×30.5 mm×3 mm (height of ceiling surface 76: 3.24 mm)
Length of cut portion of strip conductor 72: 5 mm
Width of strip conductor 72: 0.42 mm
y coordinate of center line of microstrip lines L0 and L2: 2.5 mm
y coordinate of center line of microstrip lines L1 and L3: 15.75 mm
y coordinate of spring contact 75: 12.75 mm

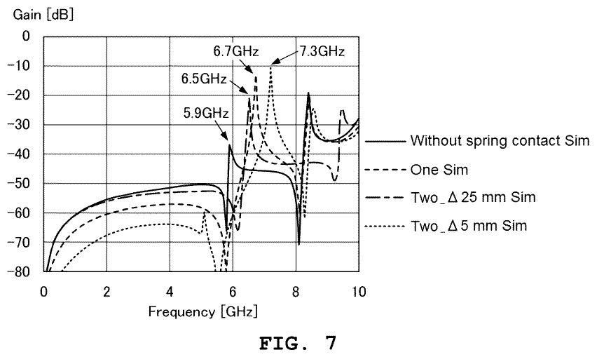

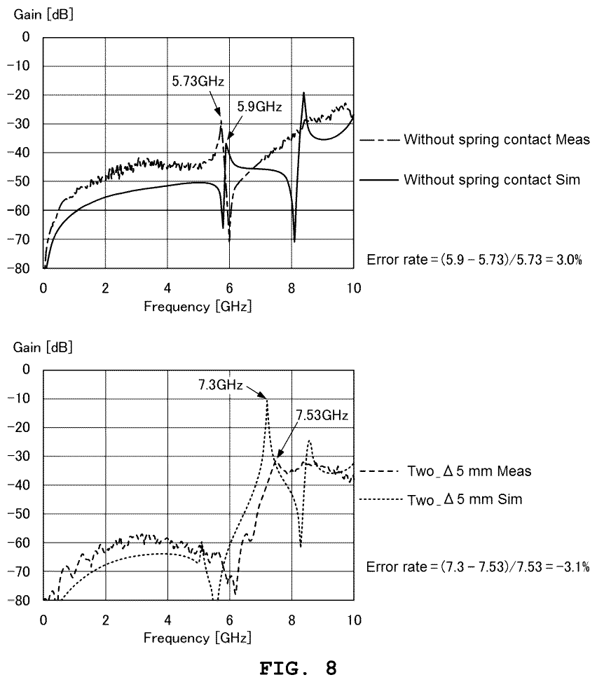

FIG. 7 is a graph showing a simulation result of transmission characteristics between the input port P0 and the output port P1.

The solid line indicates the transmission characteristics of a model (hereinafter, also referred to as a “model M0”) in which no spring contact 75 is disposed. In these transmission characteristics, a peak of cavity resonance is observed around 5.9 GHZ.

The dashed line indicates the transmission characteristics of the model M1 with one spring contact 75 disposed, as shown in FIG. 5A. In these transmission characteristics, a peak of cavity resonance is observed around 6.7 GHZ.

The alternate long and short dashed line indicates the transmission characteristics of the model M2 with two spring contacts 75 disposed 25 mm apart from each other, as shown in FIG. 5B. In these transmission characteristics, a peak of cavity resonance is observed around 6.5 GHZ.

The dotted line indicates the transmission characteristics of the model M3 with two spring contacts 75 disposed 5 mm apart from each other, as shown in FIG. 5C. In these transmission characteristics, a peak of cavity resonance is observed around 7.3 GHZ.

From the above simulation results, it can be seen that by disposing the spring contact 15 inside the shield case 31, the cavity resonance frequency can be shifted to a higher frequency. In particular, it is considered effective to dispose a plurality of spring contacts 15 in the vicinity of the center of the shield case 31.

Hereinafter, a result of evaluating the cavity resonance frequency in the shield case 31 in the high-frequency circuit 100 of the present embodiment based on measurements of an experimental board having a configuration corresponding to the above-described simulation model will be described.

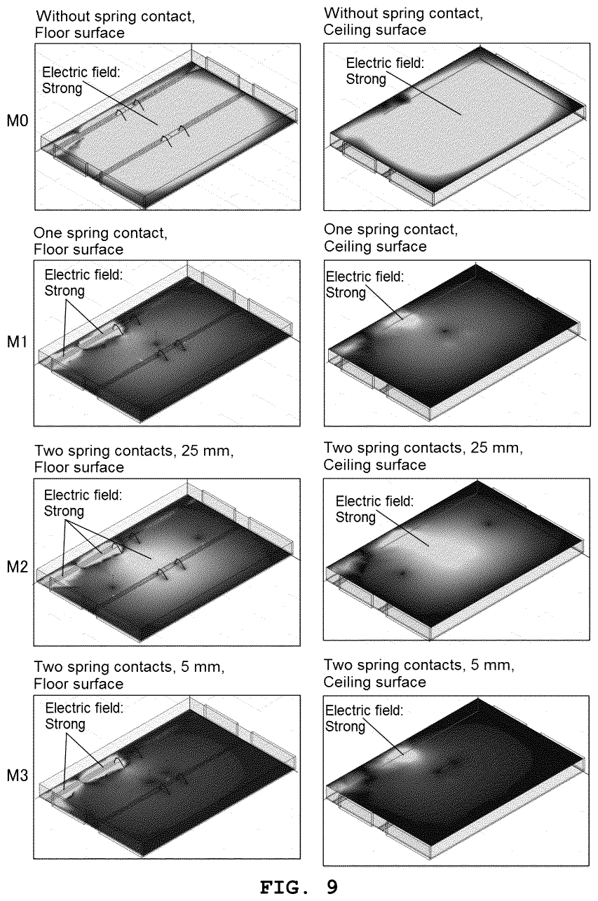

FIG. 8 is a graph showing a result of measuring transmission characteristics between the input port P0 and the output port P1 using a network analyzer and the simulation result.

The graph in the upper part of FIG. 8 shows the transmission characteristics of the experimental board in which no spring contact is disposed, indicated by the alternate long and short dashed line, and the transmission characteristics of the model M0 in which no spring contact is disposed (the same as the solid line in FIG. 7), indicated by the solid line.

In the transmission characteristics of the experimental board, a peak of cavity resonance is observed at 5.73 GHZ. The error rate of the cavity resonance frequency of 5.9 GHZ of the transmission characteristics of the model M0, when the cavity resonance frequency of 5.73 GHz of the transmission characteristics of the experimental board is regarded as a true value, is 3.0%.

The graph in the lower part of FIG. 8 shows the transmission characteristics of the experimental board with two spring contacts disposed 5 mm apart from each other, indicated by the dashed line, and the transmission characteristics of the model M3 with two spring contacts disposed 5 mm apart from each other (the same as the dotted line in FIG. 7), indicated by the dotted line.

In the transmission characteristics of the experimental board, a peak of cavity resonance is observed at 7.53 GHZ. The error rate of the cavity resonance frequency of 7.3 GHZ of the transmission characteristics of the model M3, when the cavity resonance frequency of 7.53 GHz of the transmission characteristics of the experimental board is regarded as a true value, is-3.1%.

That is, with the configuration of the high-frequency circuit 100 of the present embodiment, the cavity resonance frequency that changes depending on the disposition of the spring contact 15 in the shield case 31 can be predicted with an error rate of approximately 3% through electromagnetic field simulation.

In general, actually measuring cavity resonance, including constructing the experimental setup, is challenging, but for the high-frequency circuit 100 of the present embodiment, the design can be efficiently advanced using electromagnetic field simulation without the need for actual measurements.

Further, in the experimental board with two spring contacts disposed 5 mm apart from each other, the isolation between the input port P0 and the output port P1 was improved from approximately-40 dB to approximately-60 dB.

FIG. 9 is a diagram showing electric field distributions at 6 GHz for the models M0 to M3, whose transmission characteristics are shown in FIG. 7. These diagrams display portions with strong electric fields in white and portions with weak electric fields in black.

In model M0, strong electric fields were observed over substantially the entire regions of the surface of the ground 73 of the shield case 60 (hereinafter, also referred to as a “floor surface”) and the ceiling surface 76.

In the model M1, relatively strong electric fields were observed in the region along the microstrip line L0 on the floor surface and the ceiling surface 76, while weaker electric fields were observed in other regions.

In the model M2, relatively strong electric fields were observed in the region along the microstrip line L0 on the floor surface and the ceiling surface 76 and in the vicinity of the center.

In the model M3, relatively strong electric fields were observed in the region along the microstrip line L0 on the floor surface and the ceiling surface 76, while weaker electric fields were observed in the other regions. This shows a similar trend to the electric field distribution of the model M1, but overall, weaker electric fields were observed as compared to the model M1.

From the above simulation results of the electric field distributions, it can be confirmed that the cavity resonance is effectively suppressed when a plurality of spring contacts 15 are disposed in the vicinity of the center of the shield case 31, as compared to a case where no spring contact 15 is disposed in the shield case 31.

As described above, the high-frequency circuit 100 according to the present embodiment has a configuration in which the peripheral edge portion of the cover 51 of the shield case 31 is electrically connected to the ground 12 of the printed circuit board 10 via the frame 41, and then the vicinity of the center of the cover 51 is electrically connected to the ground 13 of the printed circuit board 10 via the spring contact 15.

The high-frequency circuit 100 according to the present embodiment configured in this manner can achieve an effect as if the space formed by the printed circuit board 10 and the inner wall of the shield case 31 is made narrower, thereby increasing the cavity resonance frequency without using a radio wave absorber.

In addition, since the disposition of the spring contact 15, which increases the cavity resonance frequency to be higher than the operating frequency, can be predicted through electromagnetic field simulation, the high-frequency circuit 100 according to the present embodiment can reduce man-hours required for performance verification.

Additionally, the high-frequency circuit 100 according to the present embodiment can facilitate the disposition of the electronic components 11 on the printed circuit board 10 because the cavity resonance frequency can be increased using the disposition of the spring contact 15 even in a case where the size of the space partitioned by the shield case 31 is increased, thereby reducing design man-hours.

Further, the high-frequency circuit 100 according to the present embodiment can effectively suppress cavity resonance by disposing the spring contact 15 in the vicinity of the center of the space of the shield case 31, thereby not affecting a degree of freedom in disposition of a plurality of other electronic components 11.

In addition, the high-frequency circuit 100 according to the present embodiment uses the spring contact 15 including the contact portion 17 that elastically comes into contact with the ceiling surface 52 of the cover 51, as the connection conductor that electrically connects the ground 13 of the printed circuit board 10 and the cover 51 of the shield case 31.

The high-frequency circuit 100 according to the present embodiment configured in this manner allows the ground 13 of the printed circuit board 10 and the cover 51 of the shield case 31 to be electrically connected reliably and easily, by covering the frame 41 with the cover 51 of the shield case 31 after disposing the plurality of electronic components 11 and the frame 41 of the shield case 31 on the printed circuit board 10.

Additionally, in the cavity resonance suppression method according to the present embodiment, in the space formed by the printed circuit board 10 and the inner wall of the shield case 31, at least one spring contact 15 electrically connected to the ground 13 is brought into contact with a part of the ceiling surface 52 of the cover 51 to electrically connect the ground 13 and the cover 51.

Further, in the cavity resonance suppression method according to the present embodiment, the spring contact 15 including the contact portion 17 that elastically comes into contact with the ceiling surface 52 of the cover 51 is used as the connection conductor that electrically connects the ground 13 of the printed circuit board 10 and the cover 51 of the shield case 31.

### DESCRIPTION OF REFERENCE NUMERALS AND SIGNS

10: printed circuit board
10a: substrate surface
11: electronic component
12, 13: ground
15: spring contact
16: bottom portion
17: contact portion
21 to 27: circuit
31 to 37: shield case
41 to 47: frame
51: cover
52: ceiling surface
100: high-frequency circuit

What is claimed is:

1. A high-frequency circuit comprising:
a printed circuit board on which a circuit including a plurality of electronic components is disposed;
a shield case that is electrically connected to a ground of the printed circuit board and covers the circuit; and
at least one connection conductor that is electrically connected to the ground in a space formed by the printed circuit board and an inner wall of the shield case,
wherein the shield case includes
a side wall portion that is surface-mounted on the ground and is electrically connected to the ground, and
a lid portion that includes a ceiling surface facing the printed circuit board and is electrically connected to the side wall portion by being in contact with the side wall portion, and
the connection conductor electrically connects the ground and the lid portion by being in contact with a part of the ceiling surface.

2. The high-frequency circuit according to claim 1,
wherein the connection conductor is a spring contact including a contact portion that elastically comes into contact with the ceiling surface.

3. A cavity resonance suppression method in a high-frequency circuit including a printed circuit board on which a circuit including a plurality of electronic components is disposed, and a shield case that is electrically connected to a ground of the printed circuit board and covers the circuit, the shield case including a side wall portion that is surface-mounted on the ground and is electrically connected to the ground, and a lid portion that includes a ceiling surface facing the printed circuit board and is electrically connected to the side wall portion by being in contact with the side wall portion, the method comprising:
electrically connecting the ground and the lid portion by bringing at least one connection conductor, which is electrically connected to the ground, into contact with a part of the ceiling surface in a space formed by the printed circuit board and an inner wall of the shield case.

4. The cavity resonance suppression method according to claim 3,
wherein a spring contact including a contact portion that elastically comes into contact with the ceiling surface is used as the connection conductor.
